(19) United States
(12) Patent Application Publication
(10) Pub. No.: US 2024/0282889 A1
(43) Pub. Date: Aug. 22, 2024

(54) STACKED STRUCTURE AND GALLIUM NITRIDE-BASED SEMICONDUCTOR DEVICE

(71) Applicants: Japan Display Inc., Tokyo (JP); TOSOH CORPORATION, Shunan-shi (JP)

(72) Inventors: Masumi NISHIMURA, Tokyo (JP); Masashi TSUBUKU, Tokyo (JP); Yoshihiro UEOKA, Ayase-shi (JP); Yuya SUEMOTO, Ayase-shi (JP); Masami MESUDA, Ayase-shi (JP)

(73) Assignees: Japan Display Inc., Tokyo (JP); TOSOH CORPORATION, Shunan-shi (JP)

(21) Appl. No.: 18/647,501

(22) Filed: Apr. 26, 2024

Related U.S. Application Data
(63) Continuation of application No. PCT/JP2022/038069, filed on Oct. 12, 2022.

(30) Foreign Application Priority Data
Oct. 28, 2021 (JP) 2021-176842

(51) Int. Cl. H01L 33/32; H01L 33/00; H01L 33/12; H01L 33/16

(52) U.S. Cl. CPC H01L 33/32; H01L 33/007; H01L 33/12; H01L 33/16

(57) ABSTRACT

A stacked structure includes an amorphous substrate, a buffer layer on the amorphous substrate, and a gallium nitride-based semiconductor layer on the buffer layer. The gallium nitride-based semiconductor layer includes at least one gallium nitride layer, and an oxygen concentration of the gallium nitride layer is less than 1×10²¹/cm³.

### CROSS-REFERENCE TO RELATED APPLICATIONS

This application is a Continuation of International Patent Application No. PCT/JP2022/038069, filed on Oct. 12, 2022, which claims the benefit of priority to Japanese Patent Application No. 2021-176842, filed on Oct. 28, 2021, the entire contents of which are incorporated herein by reference.

### FIELD

An embodiment of the present invention relates to a stacked structure including a gallium nitride-based semiconductor layer formed on an amorphous substrate, and a gallium nitride-based semiconductor device configured by the stacked structure.

### BACKGROUND

Gallium nitride is used in light-emitting diodes and is expected to find applications in power transistors and integrated circuits as a next-generation semiconductor material. The gallium nitride is formed by the metal organic chemical vapor deposition (MOCVD) method. The growth of gallium nitride by MOCVD requires heating the substrate to 1,000° C. or higher, which is problematic because the power consumption required to manufacture the device is enormous. Therefore, development of technologies to fabricate crystalline gallium nitride films using the sputtering method, which enables deposition even at low temperatures, is underway. For example, a gallium nitride sputtering target is used to deposit a crystalline gallium nitride layer on a single-crystal silicon or sapphire substrate.

For the growth of gallium nitride films, substrates with crystallinity, such as sapphire and single-crystal silicon substrates, are used. However, the sapphire substrate and single-crystal silicon substrate are expensive, and it is difficult to increase the substrate size. If amorphous substrates, such as glass substrates used in liquid crystal displays, can be used as substrates for forming the gallium nitride film, the cost of substrates can be reduced, and it will be easier to increase the area of substrates. However, so far, there is no reported case of high-quality gallium nitride with crystalline quality on an amorphous substrate such as a glass substrate.

### SUMMARY

A stacked structure in an embodiment according to the present invention includes an amorphous substrate, a buffer layer on the amorphous substrate, and a gallium nitride-based semiconductor layer on the buffer layer. The gallium nitride-based semiconductor layer includes at least one gallium nitride layer, and an oxygen concentration of the gallium nitride layer is less than 1×10²¹/cm³.

A gallium nitride-based semiconductor device in an embodiment according to the present invention includes an amorphous substrate, a buffer layer on the amorphous substrate, and a gallium nitride-based semiconductor layer on the buffer layer. The gallium nitride-based semiconductor layer includes at least one gallium nitride layer, and an oxygen concentration of the gallium nitride layer is less than 1×10²¹/cm³.

### BRIEF DESCRIPTION OF DRAWINGS

FIG. 1 is a configuration of a stacked structure according to an embodiment of the present invention.

FIG. 2A is a structure of a light-emitting device that includes a configuration of a stacked structure according to an embodiment of the present invention.

FIG. 2B is a structure of a light-emitting device that includes a configuration of a stacked structure according to an embodiment of the present invention.

FIG. 3 is a structure of a transistor that includes a configuration of a stacked structure according to an embodiment of the present invention.

FIG. 4 is a result of a secondary ion mass spectrometry measurement of the content of oxygen, carbon, hydrogen, and fluorine in the gallium nitride layer shown in an example of the present invention.

### DESCRIPTION OF EMBODIMENTS

Hereinafter, embodiments of the present invention are described with reference to the drawings. However, the present invention can be implemented in many different aspects and should not be construed as being limited to the description of the following embodiments. For the sake of clarifying the explanation, the drawings may be expressed schematically with respect to the width, thickness, shape, and the like of each part compared to the actual aspect, but this is only an example and does not limit the interpretation of the present invention. For this specification and each drawing, elements similar to those described previously with respect to previous drawings may be given the same reference sign (or a number followed by a, b, etc.) and a detailed description may be omitted as appropriate. The terms “first” and “second” appended to each element are a convenience sign used to distinguish them and have no further meaning except as otherwise explained.

As used herein, where a member or region is “on” (or “below”) another member or region, this includes cases where it is not only directly on (or just under) the other member or region but also above (or below) the other member or region, unless otherwise specified. That is, it includes the case where another component is included in between above (or below) other members or regions.

### 1. Stacked Structure

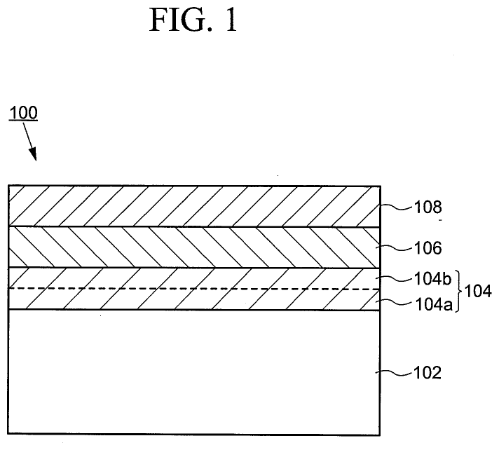

FIG. 1 shows an example structure of a stacked structure 100 in accordance with an embodiment of the present invention. The stacked structure 100 includes an amorphous substrate 102, a buffer layer 106 on the amorphous substrate 102, and a gallium nitride-based semiconductor layer 108 on the buffer layer 106. The stacked structure 100 may include an underlying insulating layer 104 between the amorphous substrate 102 and the buffer layer 106.

### 1-1. Amorphous Substrate

The amorphous substrate 102 preferably has a low coefficient of thermal expansion, a high strain point, and a high surface flatness. For example, the amorphous substrate 102 preferably has an expansion coefficient lower than 50×10⁻⁷/° C. and a strain point of 600° C. or higher. The amorphous substrate 102 in this embodiment only needs to have a heat resistance of about 700° C. and is not required to have a heat resistance of 1000° C. or higher which is required for sapphire substrates for example. The amorphous substrate 102 preferably contains 0.1% or less of an alkali metal such as sodium (Na).

As the amorphous substrate 102 that meets these characteristics, for example, a glass substrate consisting of at least one of aluminoborosilicate glass and aluminosilicate glass can be used, and it is preferred that the glass substrate be an alkali-free glass substrate. Such glass substrates are used in liquid crystal displays and organic electroluminescence (OLED) displays, and large-area glass substrates, called mother glass, are available in the market. Using the glass substrate as the amorphous substrate 102 allows the formation of the gallium nitride-based semiconductor layer 108 on the large-area glass substrate.

A flexible resin substrate such as a polyimide substrate, acrylic substrate, siloxane substrate, or fluoropolymer substrate can be used as the amorphous substrate 102. A quartz glass substrate can also be used as the amorphous substrate 102.

### 1-2. Underlying Insulating Layer

As shown in FIG. 1, the underlying insulating layer 104 may be disposed on top of the amorphous substrate 102. The underlying insulating layer 104 is formed of an inorganic insulating film. A silicon nitride film, silicon oxide film, silicon oxynitride film, aluminum nitride film, aluminum oxide film, aluminum oxynitride film, or the like can be used as the inorganic insulating film. The underlying insulating layer 104 has a single-layer structure with these inorganic insulating films or a multilayer structure with a plurality of inorganic insulating films. FIG. 1 shows a configuration in which the underlying insulating layer 104 has a stacked structure. FIG. 1 shows, as an example, an example where the underlying insulating layer 104 is formed of a silicon nitride layer 104a disposed in contact with the amorphous substrate 102 and a silicon oxide layer 104b disposed thereon.

The silicon nitride layer 104a has a function of preventing impurities contained in the amorphous substrate 102 from diffusing into the buffer layer 106 and the gallium nitride-based semiconductor layer 108. A particularly problematic impurity is an alkali metal such as sodium, which is contained in trace amounts in the amorphous substrate 102. The silicon nitride layer 104a can prevent diffusion of alkali metals as long as the film thickness is 20 nm or more. The thickness of the silicon nitride layer 104a is preferably, for example, 20 nm or more and 500 nm or less, preferably 100 nm or more and 300 nm or less, and can be formed with a film thickness of, for example, 150 nm. The silicon oxide layer 104b can increase the adhesiveness of the buffer layer 106 and prevent delamination. The silicon oxide layer 104b preferably has a film thickness of 20 nm or more. The thickness of the silicon oxide layer 104b is preferably 20 nm or more and 500 nm or less, preferably 50 nm or more and 200 nm or less, and can be formed with a thickness of, for example, 100 nm.

The underlying insulating layer 104 on the amorphous substrate 102 prevents impurity diffusion into the gallium nitride-based semiconductor layer 108 and makes it highly pure. Thereby, it is possible to form the gallium nitride-based semiconductor layer 108 with high crystallinity.

### 1-3. Buffer Layer

The buffer layer 106 is disposed on the amorphous substrate 102. The buffer layer 106 is preferably crystalline, that is, at least one of a crystalline metal and a metal compound. The crystallinity of the buffer layer 106 is preferably oriented, and the orientation of the buffer layer 106 is preferably c-axis oriented. The buffer layer 106 is preferably crystalline with rotational symmetry, for example, its crystalline surface preferably has six-fold symmetry. For example, the buffer layer 106 is preferably a hexagonal close-packed structure, a face-centered cubic structure, or an equivalent structure. Here, the hexagonal close-packed structure or a structure equivalent to the face-centered cubic structure includes a crystal structure in which the c-axis is not 90 degrees to the a-axis and b-axis. The buffer layer 106 using a conductive material having a hexagonal close-packed structure or a structure equivalent thereto is preferably oriented in the (0001) direction, that is, in the c-axis direction with respect to the amorphous substrate 102 (hereinafter referred to as (0001) orientation of the hexagonal close-packed structure). The buffer layer 106 having a face-centered cubic structure or an equivalent structure is preferably oriented in the (111) direction with respect to the amorphous substrate 102 (hereinafter referred to as (111) orientation of the face-centered cubic structure).

The buffer layer 106 is disposed between the amorphous substrate 102 and the gallium nitride-based semiconductor layer 108. In order to form the gallium nitride-based semiconductor layer 108 having crystallinity on the amorphous substrate 102, the buffer layer 106 has a function as a buffer layer to relax the lattice mismatch. The buffer layer 106 has crystallinity as described above, which enables the crystallization of the gallium nitride-based semiconductor layer 108. In other words, the buffer layer 106 has a crystalline surface with c-axis orientation and six-fold rotational symmetry, such as a hexagonal close-packed structure or a face-centered cubic structure, so that the orientation of the gallium nitride-based semiconductor layer 108 can be controlled so that the c-axis of the layer 108 grows in the film thickness direction.

The buffer layer 106 is preferred to have a flat surface. When the flatness of the surface of the buffer layer 106 is expressed in terms of arithmetic mean roughness (Ra), the value is preferably smaller than 2.5 nm and more preferably smaller than 2.3 nm. The crystallinity of the gallium nitride-based semiconductor layer 108 is enhanced by the buffer layer 106 having a flat surface. The Ra of the buffer layer 106 is preferable the smaller it is, for example, the arithmetic mean roughness (Ra) should be over 0 nm, 0.1 nm or more, preferably 0.01 nm or more. The surface roughness of the buffer layer 106 can be measured using an atomic force microscope (AFM).

The buffer layer 106 is preferably crystalline and thin. There is no particular limitation on the thickness of the buffer layer 106 as long as it can be regarded as a thin film. However, if the film thickness is excessively thin, the surface flatness may be inferior and the film may not be crystalline. On the other hand, if the film thickness of the buffer layer 106 is excessively thick, the surface morphology peculiar to the metal will appear due to crystallization and the surface planarity will be reduced. Therefore, the film thickness of the buffer layer 106 is preferably 5 nm or more and 500 nm or less and is more preferably 10 nm or more and 200 nm or less. The film thickness of the buffer layer 106 can be measured with a contact step meter, an optical film thickness meter (ellipsometry), or from images obtained with a scanning electron microscope (SEM) or transmission electron microscope (TEM).

The buffer layer 106 is formed of metal. Titanium (Ti) and aluminum (Al) are preferably used as metal materials to form the buffer layer 106, and silver (Ag), nickel (Ni), copper (Cu), strontium (Sr), rhodium (Rh), palladium (Pd), iridium (Ir), platinum (Pt) and gold (Au) may also be used. The buffer layer 106 may also use metal oxide materials such as zinc oxide (ZnO) and titanium dioxide (TiO₂).

This type of buffer layer 106 can be prepared by sputtering or electron beam vacuum evaporation.

The buffer layer 106 may also be formed with an insulating layer instead of a metallic layer. That is, the buffer layer 106 may also be formed of an insulating material.

Aluminum nitride (AlN), aluminum oxide (Al₂O₃) and the like can be used as the insulating buffer layer 106. The insulating buffer layer 106 is preferably of the same crystallinity as described above and has a similar film thickness.

### 1-4. Gallium Nitride-Based Semiconductor Layer

The gallium nitride-based semiconductor layer 108 includes at least one gallium nitride (GaN) layer. For example, the gallium nitride-based semiconductor layer 108 is a single gallium nitride layer. The gallium nitride-based semiconductor layer 108 includes a gallium nitride layer and further includes at least one layer selected from an indium gallium nitride (InGaN) layer and an aluminum gallium nitride (AlGaN) layer, which are stacked. The gallium nitride layer, the indium gallium nitride layer and the aluminum gallium nitride layer, which form the gallium nitride-based semiconductor layer 108, are preferably stoichiometric in composition, but may deviate from stoichiometric composition.

The gallium nitride-based semiconductor layer 108 preferably has crystallinity. That is, the gallium nitride layer forming the gallium nitride-based semiconductor layer 108 is preferably crystalline. The gallium nitride layer is preferably single crystalline and may be polycrystalline, microcrystalline, or nanocrystalline. The crystal structure of the gallium nitride layer preferably has a wurtzite structure. The gallium nitride layer forming the gallium nitride-based semiconductor layer 108 preferably has a c-axis orientation or a (111) orientation.

The conductive type of the gallium nitride layers forming some or all of the gallium nitride-based semiconductor layer 108 may be substantially intrinsic or may be an n-type or p-type conductive type. The gallium nitride layers may contain dopants for valence control. The n-type gallium nitride layer may be doped with one element selected from silicon (Si) or germanium (Ge) as a dopant. The p-type gallium nitride layer may be doped with one element selected from magnesium (Mg), zinc (Zn), cadmium (Cd) and beryllium (Be) as a dopant. The n-type gallium nitride layer is preferred to have a carrier concentration of 1×10¹⁸/cm³ or higher. The p-type gallium nitride layer is preferred to have a carrier concentration of 5×10¹⁶/cm³ or more. The substantially intrinsic (otherwise known as high resistivity) gallium nitride layer may also contain zinc (Zn) as a dopant.

The gallium nitride layer forming part or all of the gallium nitride-based semiconductor layer 108 is disposed in contact with the buffer layer 106. The gallium nitride layer is deposited on the buffer layer 106. As mentioned above, the buffer layer 106 has a c-axis oriented crystal plane, which enables the formation of a gallium nitride layer having a c-axis or (111) orientation. The gallium nitride layer may contain an amorphous structure in the region near the interface where it contacts the buffer layer 106, although it is preferred that the layer is crystalline in the region away from the interface (bulk). The crystallinity of the gallium nitride layer forming part or all of the gallium nitride-based semiconductor layer 108 improves the performance of the gallium nitride-based semiconductor device. For example, when the gallium nitride-based semiconductor device is a light-emitting device, the luminous intensity can be enhanced, and when the device is an active device such as a transistor, the carrier mobility can be enhanced.

The gallium nitride layer forming part or all of the gallium nitride-based semiconductor layer 108 may contain oxygen (O), carbon (C), hydrogen (H) and fluorine (F) as impurity elements other than elements added as dopants. The concentration of oxygen contained in the gallium nitride layer is preferably 2×10²¹/cm³ or less, and 1×10²¹/cm³ or less is more preferred. The concentration of carbon in the gallium nitride layer is preferably 5×10¹⁹/cm³ or less, and 3×10¹⁹/cm³ or less is more preferred. The concentration of hydrogen in the gallium nitride layer is preferably 3×10²⁰/cm³ or less, and 2×10²⁰/cm³ or less is more preferred. The concentration of fluorine in the gallium nitride layer is preferably 1×10¹⁹/cm³ or less, and 5×10¹⁷/cm³ or less is more preferred.

The lower limit values of oxygen (O), carbon (C), hydrogen (H) and fluorine (F) as impurity elements are not limited in terms of high purity of the gallium nitride layer, and less is preferred, however, the lower limit may be equal to or higher than the lower limit of detection of the measurement device that detects these impurity elements. When the oxygen (O), carbon (C), hydrogen (H) and fluorine (F) concentrations in the gallium nitride layer are measured by secondary ion mass spectrometry, they may be specified as equal to or above the background level. For example, the lower limit may be set at 6×10¹⁶/cm³ or more for oxygen (O), 4×10¹⁶/cm³ or more for carbon (C), 2×10¹⁷/cm³ or more for hydrogen (H) and 2×10¹⁵/cm³ or more for fluorine (F).

It is not preferred if the impurity concentration in the gallium nitride layer is high, as the crystallinity will decrease and increase the density of defect levels that act as carrier traps. Oxygen in the gallium nitride layer acts as a dopant, so exceeding the above range may change the conductive properties and degrade the device characteristics. Hydrogen in the gallium nitride layer may passivate and inactivate p-type dopants in particular, so it is preferable that the above range is not exceeded. Carbon in the gallium nitride layer should not exceed the above range, as it may form crystal defects and form defective levels, reducing luminous efficiency.

The concentration of these impurity elements is based on measurements obtained by the secondary ion mass spectrometry method. The above impurity concentrations are based on values obtained by measuring the secondary ion intensity in the depth direction (film thickness direction) for each element using cesium ions (Cs⁺) as the primary ion, and quantifying based on the secondary ion intensity.

These impurity elements such as oxygen, hydrogen, carbon and fluorine in the gallium nitride-based semiconductor layer 108 result from impurities in the sputtering target. These impurity elements result from residual gases in the deposition chamber of the sputtering apparatus. These impurity elements in the gallium nitride layer are considered to be contaminated in the film during sputtering deposition from these sources. Unlike impurities that are intentionally added for the purpose of valence control, these impurity elements can be said to be impurities that are inevitable.

The crystallinity of the gallium nitride layer can be enhanced by increasing the purity of the gallium nitride layer so that the concentration of oxygen, carbon, hydrogen and fluorine inevitably contained in the gallium nitride layer forming part or all of the gallium nitride-based semiconductor layer 108 is in the numerical range as described above. That is, the stacked structure 100 according to the present embodiment can enhance the crystallinity of the gallium nitride layer forming part or all of the gallium nitride-based semiconductor layer 108 disposed on the amorphous substrate 102 by increasing the purity of the gallium nitride layer.

### 2. Method of Manufacturing Stacked Structure.

The stacked structure 100 of the present embodiment is not limited to any method of manufacturing. The stacked structure 100 of the present embodiment may suitably be fabricated according to the following manufacturing method.

The method of manufacturing the stacked structure 100 may include the processes of forming the buffer layer 106 on the amorphous substrate 102 and the gallium nitride-based semiconductor layer 108 on the buffer layer 106. When providing the underlying insulating layer 104, the process includes forming the underlying insulating layer 104 on the amorphous substrate 102 before forming the buffer layer 106. The process of forming the gallium nitride-based semiconductor layer 108 includes a deposition process using the sputtering method. In the following description, the process of forming the underlying insulating layer 104 is included.

### 2-1. Preparation of Amorphous Substrate

A glass substrate is used as the amorphous substrate 102. The glass substrate is an alkali-free glass substrate formed of aluminoborosilicate glass, aluminosilicate glass, or the like. The amorphous substrate 102 is cleaned to form a clean surface. The method of cleaning is optional, for example, cleaning is performed with a mixed cleaning solution containing sulfuric acid and hydrogen peroxide or hydrochloric acid and hydrogen peroxide, followed by an ultrapure water rinse to remove the mixed cleaning solution.

### 2-2. Forming Underlying Insulating Layer

The underlying insulating layer 104 is formed by a silicon nitride layer 104a and a silicon oxide layer 104b. There is no limitation on the method of forming the silicon nitride layer 104a and the silicon oxide layer 104b. For example, the silicon nitride layer 104a is prepared by a plasma CVD (Chemical Vapor Deposition) method using reaction gases such as silane (SiH₄), ammonia (NH₃) and nitrogen (N₂). The silicon oxide layer 104b is prepared by a plasma CVD method using reaction gases such as silane (SiH₄), nitrous oxide (N₂O) and tetraethyl orthosilicate (TEOS). When the plasma CVD apparatus is equipped with multiple deposition chambers, the silicon nitride layer 104a and the silicon oxide layer 104b can be continuously deposited. The silicon nitride layer 104a may be formed by reactive sputtering using silicon as the sputtering target, and the silicon oxide layer 104b may be formed using quartz as the sputtering target.

The silicon nitride layer 104a is formed with a thickness of 20 nm or more and 500 nm or less, preferably 100 nm or more and 300 nm or less, for example, 150 nm, as described above. The silicon oxide layer 104b is formed with a thickness of 20 nm or more and 500 nm or less, preferably 50 nm or more and 200 nm or less, for example, 100 nm.

### 2-3. Forming Buffer Layer

The buffer layer 106 is formed on the underlying insulating layer 104. The buffer layer 106 is prepared by a sputtering method or vacuum evaporation method. As a sputtering method, known sputtering methods can be used. DC sputtering, RF sputtering, AC sputtering, DC magnetron sputtering, RF magnetron sputtering, pulsed sputtering, ion beam sputtering and induced plasma-assisted sputtering methods are among the known methods. Among these, the DC magnetron sputtering or RF magnetron sputtering methods are preferred for uniform and fast deposition on large-area glass substrates.

When the buffer layer 106 is prepared by sputtering, metal, oxide or nitride targets are used as sputtering targets. As the buffer layer 106 is preferably to have orientation, the target material is preferably of high purity, and a purity of 5N (99.999%) or more is preferred. To prevent abnormal discharges and suppress particle generation, it is preferable to use a target material with a low defect density and a smooth surface.

When a metal buffer layer is formed as the buffer layer 106, titanium (Ti) and aluminum (Al) are preferred as the metal material, as described above. The buffer layer 106 may also be formed with other metals such as silver (Ag), nickel (Ni), copper (Cu), strontium (Sr), rhodium (Rh), palladium (Pd), iridium (Ir), platinum (Pt) and gold (Au). The buffer layer 106 may be formed of a metal oxide such as zinc oxide (ZnO) or titanium dioxide (TiO₂) instead of a metal. The buffer layer 106 may also be formed of an insulating material such as aluminum nitride (AlN) or aluminum oxide (Al₂O₃). The buffer layer 106 is formed with a thickness of 5 nm or more and 500 nm or less, preferably 10 nm or more and 200 nm or less.

When the buffer layer 106 is formed of the metal, a high-purity metal is used as a sputtering target. When the buffer layer 106 is formed of the metal oxide, a sintered metal oxide is used as the sputtering target. When the buffer layer 106 is formed of the insulating material, a sintered insulating material is used as the sputtering target. These sputtering targets are brazed to a backing plate of copper (Cu), aluminum (Al) or stainless steel. When the sputtering target is metal, the backing plate may be formed in one piece.

It is preferable to use a deposition apparatus capable of high vacuum evacuation for the preparation of the buffer layer 106. For example, when the buffer layer 106 is prepared by sputtering, the ultimate vacuum of the deposition chamber of the sputtering equipment should be 1×10⁻⁴ Pa or lower. It is possible to increase the degree of ultimate vacuum in the deposition chamber to remove residual gases as much as possible and reduce impurities contained in the buffer layer 106 during film deposition, thereby enhancing orientation film. To orient the buffer layer 106, the substrate temperature is preferably heated to between 100° C. and 300° C. It is possible to form a highly oriented buffer layer 106 with c-axis orientation by depositing the film at the substrate temperature in this range.

### 2-4. Preparation of Gallium Nitride-Based Semiconductor Layer

In this embodiment, the gallium nitride-based semiconductor layer 108 is prepared by a sputtering method. A gallium nitride-based sintered material is used as the sputtering target. When the gallium nitride layer is formed as the gallium nitride-based semiconductor layer 108, a gallium nitride sintered material is used as the sputtering target. From the viewpoint of improving the crystallinity of the gallium nitride layer, the lower the oxygen content in the sputtering target, the better. For example, the oxygen content in a gallium nitride sintered material used as a sputtering target is preferably 3 at % or less in atomic percentage, and 1 at % or less is even more preferred. In the gallium nitride sintered material, the content of metallic impurities other than gallium is preferably 0.1 at % or less, and 0.01 at % or less is even more preferred. The resistivity of the sputtering target with gallium nitride sintered material is preferably 1×10² Ω cm or less, the density is preferably 3.0 g/cm³ or more and 5.4 g/cm³ or less, and there is preferably no precipitation of gallium metal. The area of the sputtering target is preferably 18 cm² or more, and 100 cm² or more is more preferred. The larger the area of the sputtering target, the more stable the discharge and the lower the gas pressure and power density. Furthermore, the uniformity of the thickness and quality of the gallium nitride layer can be improved by using a sputtering target of such a size.

As for sputtering methods, DC sputtering method, RF sputtering method, AC sputtering method, DC magnetron sputtering method, RF magnetron sputtering method, pulse sputtering method, and ion beam sputtering method and induced plasma assisted sputtering method can be used. In these methods, DC magnetron sputtering and RF magnetron sputtering methods are preferred selections as they are capable of handling the large area of the amorphous substrate 102. In the DC and RF magnetron sputtering methods, the moving magnet method is preferred, as it allows erosion of the sputtering target over its entire surface, thereby ensuring effective use of the material.

The gas pressure during deposition of the gallium nitride layer by sputtering is less than 0.3 Pa, less than 0.1 Pa is preferred, and less than 0.08 Pa is even preferred. The lower gas pressure during sputtering deposition enhances the surface diffusion of sputter particles adhering to the deposited surface and improves crystallinity.

The ultimate vacuum in the deposition chamber of the sputtering apparatus is preferably less than 3×10⁻⁵ Pa, and less than 1×10⁻⁵ Pa. A baking treatment of the deposition chamber and vacuum exhaust system is preferred in order to remove residual moisture in the deposition chamber and to enable high vacuum evacuation. In this way, the ultimate vacuum in the deposition chamber is being increased, so that residual gases are less likely to be contaminated as impurities in the gallium nitride layer, and crystallinity can be improved.

Before depositing the gallium nitride layer, the amorphous substrate 102 (that is, the surface of the buffer layer 106, which is the deposited surface) is preferably subjected to reverse sputtering. The reverse sputtering is a method of cleaning the surface by irradiating noble gas ions such as argon (Ar) onto the amorphous substrate 102, rather than on the sputtering target side. The reverse sputtering cleans the surface of the amorphous substrate 102 (that is, the surface of the buffer layer 106, which is the deposition surface), planarizes the minute irregularities on the surface and removes factors that inhibit crystal growth. It is preferable that the sputtering apparatus has a dedicated processing chamber for the reverse sputtering in addition to the deposition chamber, so that the film can be deposited while keeping the surface of the amorphous substrate 102 (that is, the surface of the buffer layer 106, which is the deposited surface) clean by sending it to the deposition chamber without exposing it to the outside air after the reverse sputtering is performed.

To improve the crystallinity of the gallium nitride layer, the substrate temperature during deposition is preferably controlled. It is possible to improve the crystallinity of the gallium nitride layer by increasing the substrate temperature, thereby enhancing the surface diffusion of sputter particles adhering to the deposited surface. The substrate temperature (also referred to as “deposition temperature”) during sputter deposition is preferably between room temperature and 600° C., and 100° C. or more and 400° C. or less is more favorable. On the other hand, at temperatures higher than 600° C., the heat resistance temperature of the amorphous substrate 102 is exceeded, the sputtering apparatus becomes expensive and the advantages of using the sputtering method become less advantageous. The substrate temperature can be from room temperature (including cases where the substrate is not intentionally heated) to higher temperatures, and preferably low-temperature deposition on the amorphous substrate 102 at 100° C. or more and 400° C. or less can improve the crystallinity of the gallium nitride layer deposited on the buffer layer 106.

The gas used for sputtering (sputter gas) is usually a noble gas such as argon (Ar), but nitrogen (N₂) gas is preferably used for the deposition of gallium nitride films. It is possible to suppress the formation of nitrogen defects by using nitrogen gas as the sputtering gas.

A power density of 5 W/cm² or less is preferred, 2.5 W/cm² or less is more preferred and 1.5 W/cm² or less is even more preferred as power during discharge. A lower limit of 0.1 W/cm² or more is preferred, and 0.3 W/cm² or more is even more preferred. The power density calculation is based on the power applied during discharge divided by the area of the sputtering target material. When the power applied during discharge is higher than 5 W/cm², coarse polycrystalline particles are more likely to detach from the sputtering target. When the power density is less than 0.1 W/cm², the discharge becomes stable and the deposition rate decreases, resulting in lower film productivity.

The thickness of the gallium nitride layer is preferably 30 nm or more, and 50 nm or more is even more preferred. With such a film thickness, it is possible to form the gallium nitride layer with crystallinity on top of the buffer layer 106. The thickness of the gallium nitride layer is preferably less than 5000 nm, preferably less than 1000 nm, more preferably, for example, less than 200 nm to 500 nm.

The present embodiment describes a method for manufacturing the gallium nitride layer as a gallium nitride-based semiconductor layer 108. It is possible to manufacture crystalline thin films with different compositions, such as an indium gallium nitride (InGaN) layer and an aluminum gallium nitride (AlGaN) layer, by changing the material of the sputtering target. In addition, it is possible to form a gallium nitride-based semiconductor layer 108 with a plurality of layers with different compositions, by using a sputtering apparatus having multiple deposition chambers and attaching a sputtering target with a different composition to each deposition chamber.

As shown in this embodiment, In the fabrication of the gallium nitride-based semiconductor layer 108, it is possible to prepare the gallium nitride-based semiconductor layer 108 with a low concentration of impurities such as oxygen, carbon, hydrogen and fluorine, and high crystallinity, by reducing the concentration of impurities such as oxygen in the sputtering target, and by performing high vacuum evacuation during sputtering deposition, and by cleaning the deposited surface by processes such as reverse sputtering. In other words, the gallium nitride layer may be prepared with the oxygen concentration less than 2×10²¹/cm³, preferably less than 1×10²¹/cm³, the carbon concentration less than 5×10¹⁹/cm³, preferably less than 3×10¹⁹/cm³, the hydrogen concentration less than 3×10²⁰/cm³, preferably less than 2×10²⁰/cm³, and the fluorine concentration less than 1×10¹⁹/cm³, preferably less than 5×10¹⁷/cm³. It is possible to prepare the stacked structure 100 in which the gallium nitride-based semiconductor layer 108 having crystallinity is formed on the amorphous substrate 102 by having such an impurity concentration.

As described above, the gallium nitride-based semiconductor layer 108 is prepared using the sputtering target consisting of gallium nitride with reduced impurities such as oxygen. In the sputtering process, the amorphous substrate 102 is subjected to a reverse sputtering process and the deposition chamber is evacuated to a high vacuum before sputtering deposition is carried out at a specified power density. The concentration of impurities such as oxygen, carbon, and hydrogen are reduced, and the gallium nitride-based semiconductor layer 108 having high crystallinity and low defect density can be obtained, by such a film forming method.

### 3. Gallium Nitride-based Semiconductor Devices

The stacked structure 100 according to the present embodiment can be used to manufacture gallium nitride-based semiconductor devices, such as light-emitting devices and transistors. An example of a device using the stacked structure 100 as the basic structure is shown below. The devices shown below are examples, and devices realized by the stacked structure 100 are not limited to the structure illustrated.

### 3-1. Light-emitting Device

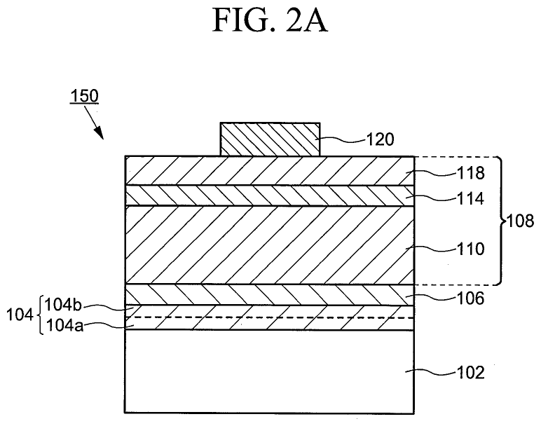

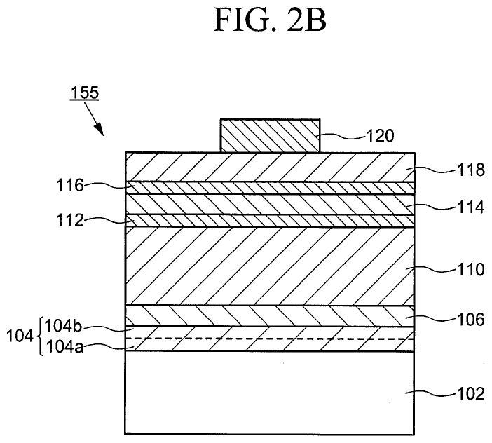

FIG. 2A shows a light-emitting device 150 as an example of a gallium nitride-based semiconductor device. The light-emitting device 150 has the configuration of the stacked structure 100, in which the base insulating layer 104, the buffer layer 106 and the gallium nitride-based semiconductor layer 108 are stacked on the amorphous substrate 102. The gallium nitride-based semiconductor layer 108 has a stacked structure including an n-type gallium nitride layer 110, an emission layer 114 and a p-type gallium nitride layer 118. An upper electrode layer 120 is disposed above the p-type gallium nitride layer 118. The upper electrode layer 120 is formed of a metallic material such as gold (Au), a titanium-gold (Ti—Au) alloy or a transparent conductive layer such as indium tin oxide (ITO). The structure of the light emitting layer 114 varies and may be formed by a quantum well layer with alternating layers of gallium nitride (GaN) and indium gallium nitride (InGaN) layers.

FIG. 2B shows a light-emitting device 155 in which the configuration of the gallium nitride-based semiconductor layer 108 differs from that of FIG. 2A. The light-emitting device 155 has a structure in which an n-type gallium nitride layer 110, an n-type aluminum gallium nitride layer 112, an indium gallium nitride layer 114 as an emission layer, a p-type aluminum gallium nitride layer 116 and a p-type gallium nitride layer 118 are stacked. As each of these layers has a different composition, they are deposited using sputtering targets corresponding to their respective compositions.

The light-emitting device 150 shown in FIG. 2A and the light-emitting device 155 shown in FIG. 2B include the structure of the stacked structure 100 shown in this embodiment. The stacked structure 100 has a gallium nitride-based semiconductor layer 108 on the amorphous substrate 102 with a reduced concentration of impurities such as oxygen, carbon and hydrogen and high crystallinity. The gallium nitride-based semiconductor layer 108 can be formed on a large area of the amorphous substrate 102, thereby increasing the number of light-emitting devices that can be individually formed from one amorphous substrate 102 and improving productivity. An LED array of light-emitting devices can be fabricated on the amorphous substrate 102, and a display device can be fabricated with the LED array.

### 3-2. Transistor

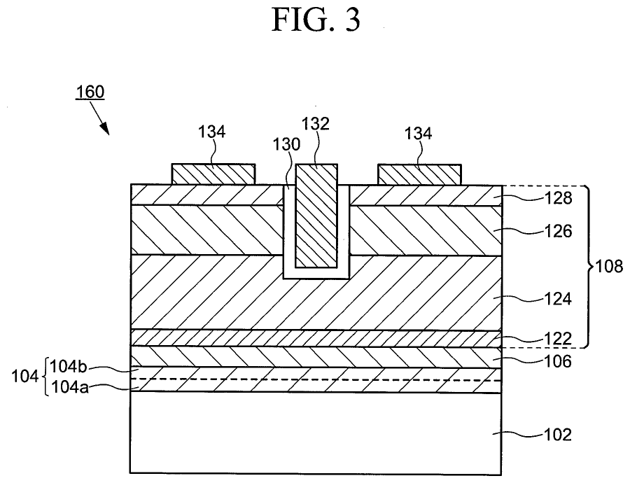

FIG. 3 shows a transistor 160 as an example of the gallium nitride-based semiconductor device. The transistor 160 includes the gallium nitride-based semiconductor layer 108 formed on the amorphous substrate 102. The gallium nitride-based semiconductor layer 108 has the stacked structure of an n+type gallium nitride layer 122, an n-type gallium nitride layer 124, a p-type gallium nitride layer 126 and an n-type gallium nitride layer 128. A gate electrode 132 is disposed to be embedded in the p-type gallium nitride layer 126 via a gate insulating layer 130. A source electrode 134 is disposed above the n-type gallium nitride layer 128. A drain electrode may be disposed by the buffer layer 106, which also serves as the drain electrode. That is, the buffer layer 106 is formed of a metal or conductive metal oxide, which can also serve as the drain electrode. The transistor 160 shown in FIG. 3 can be used, for example, as a power transistor.

An active layer of the transistor 160 is formed by the gallium nitride-based semiconductor layer 108 on the amorphous substrate 102. The gallium nitride-based semiconductor layer 108 has high crystallinity with reduced concentrations of impurities such as oxygen, carbon and hydrogen, and reduced defect density, thus providing a transistor with excellent switching characteristics and high-speed operation at a low cost.

### EXAMPLE

An example of the stacked structure 100 is shown below, but the present invention is not limited to this example.

An alkali-free glass substrate was used as the amorphous substrate 102. A silicon nitride layer 104a and a silicon oxide layer 104b were formed on the alkali-free glass substrate with a thickness of 150 nm and 100 nm, respectively, as the underlying insulating layer 104. The silicon nitride layer 104a and the silicon oxide layer 104b were prepared by the plasma CVD method. The silicon nitride layer 104a was deposited using silane (SiH₄), ammonia (NH₃) and nitrogen (N₂) as reaction gases at an RF power density of 0.24 W/cm² and a substrate temperature of 400° C. The silicon oxide layer 104b was deposited using silane (SiH₄) and nitrous oxide (N₂O) as reaction gases at an RF power density of 0.61 W/cm² and a substrate temperature of 380° C.

A titanium (Ti) layer was formed as the buffer layer 106 on top of the underlying insulating layer 104 to a thickness of 50 nm. The titanium (Ti) layer was deposited at room temperature without substrate heating using a titanium (Ti) target by sputtering method.

A gallium nitride layer was prepared as the gallium nitride-based semiconductor layer 108 by sputtering. The sputtering conditions are as follows.
Discharge mode: RF sputtering
Deposition apparatus: Magnetron sputtering apparatus
Target material: Gallium nitride (Oxygen content 7 atm %)
Target size: 120 mm ϕ
Distance between target and substrate: 150 mm
Deposition pressure: 0.3 Pa
Sputter gas: Nitrogen
RF power: 100 W
Deposition temperature: 200° C.
Film thickness: 100 nm
Heat treatment temperature: 600° C.

The impurity concentration in the gallium nitride layer prepared under the conditions described above was evaluated by secondary ion mass spectrometry. The concentrations of oxygen, hydrogen, carbon and fluorine were measured as impurities in the gallium nitride layer.

The conditions for analysis by secondary ion mass spectrometry are shown below.
Measuring equipment: PHI ADEPT1010
Primary ion species: Cs⁺
Primary acceleration voltage: 2.0 kV
Raster scan area: 90 μm×90 μm

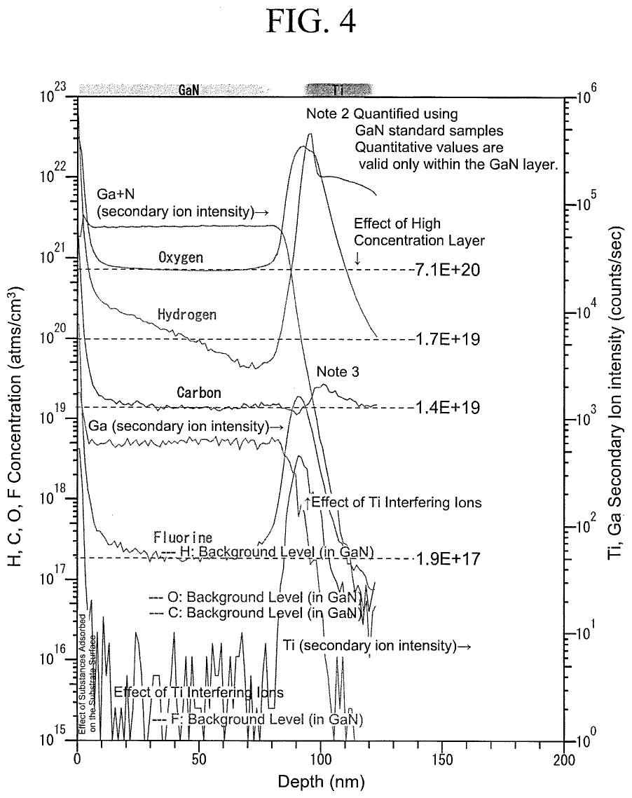

FIG. 4 shows a graph showing the depth profile of oxygen, hydrogen, carbon and fluorine elements in the gallium nitride layer, as measured by secondary ion mass spectrometry. In the graph shown in FIG. 4, the horizontal axis indicates the depth from the surface of the gallium nitride film and the vertical axis indicates the concentration of each element converted from the secondary ion intensity.

The graph in FIG. 4 shows the back-ground levels (detection limits) of oxygen, hydrogen, carbon, and fluorine. The background is 6.0×10¹⁶/cm³ for oxygen, 2.1×10¹⁷/cm³ for hydrogen, 4.5×10¹⁶/cm³ for carbon and 1.9×10¹⁵/cm³ for fluorine. The secondary ion intensities of gallium+nitrogen (Ga+N), gallium (Ga) and titanium (Ti) are overlaid as matrix markers in the graph shown in FIG. 4. In the graph shown in FIG. 4, the flat areas of gallium+nitrogen (Ga+N) and gallium (Ga) secondary ion intensities, shown as matrix markers, are the areas where the gallium nitride layer is definitely present. From the graph in FIG. 4, it can be seen that the gallium nitride layer is present from the surface to around 80 μm, after which the buffer layer, the titanium layer, is present. Quantitative values for oxygen, hydrogen, carbon and fluorine elements can be read from the regions where the matrix markers are flat. Due to the nature of secondary ion mass spectrometry, a pile-up of the profile is observed near the surface of the film and near the interface due to charge-up and impurity contamination, so this area should not be taken into account.

Table 1 shows the concentrations of oxygen, hydrogen, carbon and fluorine in the gallium nitride layer, as read from the graph shown in FIG. 4. As shown in Table 1, the gallium nitride layer prepared in the present case had a hydrogen concentration of 9.7×10¹⁹/cm³, a carbon concentration of 1.4×10¹⁹/cm³, an oxygen concentration of 7.1×10²⁰/cm³ and a fluorine concentration of 1.9×10¹⁷/cm³. The hydrogen profile shows a tendency to decrease for a while as it progresses from the surface to the inside of the gallium nitride layer, but in reading the quantitative values, the values near the center of the film were read.

TABLE 1

| Element | Concentration [atms/cm³] |
|---|---|
| Oxygen: O | 7.1 × 10²⁰ |
| Carbon: C | 1.4 × 10¹⁹ |
| Hydrogen: H | 9.7 × 10¹⁹ |
| Fluorine: F | 1.9 × 10¹⁷ |

This example shows that it is possible to prepare a gallium nitride layer with excellent crystallinity even when using an amorphous substrate such as a glass substrate by reducing as much as possible the impurities that inevitably enter when gallium nitride films are prepared by the sputtering method.

What is claimed is:

1. A stacked structure, comprising:
an amorphous substrate;
a buffer layer on the amorphous substrate; and
a gallium nitride-based semiconductor layer on the buffer layer,
wherein the gallium nitride-based semiconductor layer includes at least one gallium nitride layer, and an oxygen concentration of the gallium nitride layer is less than 1×10²¹/cm³.

2. The stacked structure according to claim 1, wherein a carbon concentration in the gallium nitride layer is less than 3×10¹⁹/cm³.

3. The stacked structure according to claim 2, wherein a hydrogen concentration in the gallium nitride layer is less than 2×10²⁰/cm³.

4. The stacked structure according to claim 3, wherein a fluorine concentration in the gallium nitride layer is less than 5×10¹⁷/cm³.

5. The stacked structure according to claim 1, wherein the gallium nitride layer is c-axis oriented.

6. The stacked structure according to claim 1, wherein the buffer layer is a c-axis oriented metal film comprising at least one element selected from titanium (Ti), aluminum (Al), silver (Ag), nickel (Ni), copper (Cu), strontium (Sr), rhodium (Rh), palladium (Pd), iridium (Ir), platinum (Pt), and gold (Au).

7. The stacked structure according to claim 1, wherein the buffer layer is a metal oxide layer, and the metal oxide layer is a c-axis oriented metal oxide film comprising one of zinc oxide (ZnO) and titanium dioxide (TiO₂).

8. The stacked structure according to claim 1, further comprising an underlying insulating layer disposed between the amorphous substrate and the buffer layer.

9. The stacked structure according to claim 1, wherein the underlying insulating layer includes a stacked structure of a silicon oxide film and a silicon nitride film.

10. The stacked structure according to claim 1, wherein the amorphous substrate is a glass substrate.

11. The stacked structure according to claim 1, wherein the amorphous substrate is a flexible resin substrate.

12. The stacked structure according to claim 1, wherein the gallium nitride layer is formed on the buffer layer by a sputtering method using a gallium nitride sputtering target.

13. A gallium nitride-based semiconductor device,
comprising:
an amorphous substrate;
a buffer layer on the amorphous substrate; and
a gallium nitride-based semiconductor layer on the buffer layer,
wherein the gallium nitride-based semiconductor layer includes at least one gallium nitride layer, and an oxygen concentration of the gallium nitride layer is less than 1×10²¹/cm 3.

14. The gallium nitride-based semiconductor device according to claim 13, wherein a carbon concentration in the gallium nitride layer is less than 3×10¹⁹/cm³.

15. The gallium nitride-based semiconductor device according to claim 14, wherein a hydrogen concentration in the gallium nitride layer is less than 2×10²⁰/cm³.

16. The gallium nitride-based semiconductor device according to claim 15, wherein a fluorine concentration in the gallium nitride layer is less than 5×10¹⁷/cm³.

17. The gallium nitride-based semiconductor device according to claim 13, wherein the gallium nitride layer is c-axis oriented.

18. The gallium nitride-based semiconductor device according to claim 13, wherein the buffer layer is a c-axis oriented metal film comprising at least one element selected from titanium (Ti), aluminum (AI), silver (Ag), nickel (Ni), copper (Cu), strontium (Sr), rhodium (Rh), palladium (Pd), iridium (Ir), platinum (Pt), and gold (Au).

19. The gallium nitride-based semiconductor device according to claim 13, wherein the buffer layer is a metal oxide layer, and the metal oxide layer is a c-axis oriented metal oxide film comprising one of zinc oxide (ZnO) and titanium dioxide (TiO₂).

20. The gallium nitride-based semiconductor device according to claim 13, wherein the amorphous substrate is a glass substrate or a flexible resin substrate.
